(19) United States
(12) Patent Application Publication
(10) Pub. No.: US 2002/0067179 A1
(43) Pub. Date: Jun. 6, 2002

(54) Probe card for testing an LSI operating on two power source voltages

(75) Inventors: Kazunari Takasugi, Tokyo (JP); Masahiro Toeda, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 10/033,293

(22) Filed: Oct. 25, 2001

(30) Foreign Application Priority Data
Oct. 26, 2000 (JP) 2000-326477

(51) Int. Cl. G01R 31/02

(52) U.S. Cl. 324/754

(57) ABSTRACT

A probe card includes low-voltage and high-voltage source pins and a plurality of signal pins. An EMI filter block is electrically connected between each source pin and a corresponding card terminal. Each EMI filter block includes a plurality of EMI filter elements connected in parallel. The low-voltage EMI filter element includes a three-terminal capacitor and a ferrite bead separately disposed, whereas the high-voltage EMI filter element includes a three-terminal capacitor having a built-in ferrite bead.

### BACKGROUND OF THE INVENTION

(a) Field of the Invention

The present invention relates to a probe card for testing an LSI operating on two power source voltages and, more particularly, to a probe card for testing an LSI (large-scale semiconductor integrated circuit) having two power supply lines for different types of semiconductor circuits having different operational voltages.

(b) Description of the Related Art

Generally, LSIs are fabricated in respective pellet areas of a semiconductor wafer, which is divided into a large number of such pellet areas by a large number of scribe lines extending in the shape of a grid. Each LSI formed in a corresponding pellet area of the wafer is subjected to a test on the wafer by using an IC tester for measurement of electric characteristics thereof.

The LSI has a plurality of electrode pads thereon through which a power source and test signals are supplied from the IC tester. The IC tester includes a test unit and an associated probe card having a large number of probe needles (pins) which contact with the respective electrode pads. In some LSIs, wherein a plurality of semiconductor circuits operate on two different power source voltages, the two different power source voltages are supplied through the different probe pins from the IC tester unless one of the power source voltages is not generated in the LSI based on the other of the power source voltages. Thus, the probe card generally includes power source pins including a high-voltage source pin and a low-voltage source pin, as well as a large number of signal output/input pins.

In the conventional probe card, the power source pins are associated with respective bypass capacitors installed on the probe card for suppressing the noise on the power source voltage. The bypass capacitor is generally implemented as a stacked ceramic capacitor having larger dimensions and formed on the top surface of the card plate opposite to the bottom surface thereof mounting thereon the probe pins. This structure, however, does not effectively remove the noise on the power source voltage due to a large distance between the terminal of the bypass capacitor and the power source pin.

If the noise on the high-voltage power source enters or affects the low-voltage power source line by capacitive coupling to cause a voltage fluctuation on the low-voltage power source line, some logic circuit operating on the low-voltage power source may have a malfunction. If the some logic circuit is such that controls the input/output buffers in the high-voltage source circuit and causes a hunting operation due to the voltage fluctuation, a high penetrating current may arise in the high-voltage source circuit. This trouble may lead to melt-down or fusion of a high-voltage source pin or a plurality of signal probe pins, and raises the cost for the test for the LSIs due to the necessity of replacement of the probe card.

### SUMMARY OF THE INVENTION

In view of the above, it is an object of the present invention to provide a probe card having two or more power source probe pins, which is capable of preventing the malfunction as described above due to the structure of the power-source probe pins in the probe card.

It is another object of the present invention to provide an IC tester including a probe card and an associated test unit for testing an LSI operating on two or more different power source voltages.

The present invention provides, in a first aspect thereof, a probe card including: a card plate; a plurality of probe pins mounted on a bottom surface of the card plate and including a first source pin, a second source pin and a plurality of signal pins; a plurality of probe terminals disposed on the card plate and including a first source terminal electrically connected to the first source pin, a second source terminal connected to the second source pin, and a plurality of signal terminals electrically connected to the respective signal pins; and first and second EMI filter blocks electrically connected between the first source pin and the first source terminal and between the second source pin and the second source terminal, respectively.

The present invention provides, in a second aspect thereof, an IC tester including a probe card and an associated test unit having a plurality of test terminals including a first power supply terminal, a second power supply terminal and a plurality of test signal terminals, the first power supply terminal supplying a first source voltage which is lower than a second source voltage supplied by the second power supply terminal, the probe card including: a card plate; a plurality of probe pins mounted on a bottom surface of the card plate and including a first source pin, a second source pin and a plurality of signal pins; a plurality of probe terminals disposed on the card plate and including a first source terminal electrically connected between the first power supply terminal and the first source pin, a second source terminal electrically connected between the second supply terminal and the second source pin, and a plurality of signal terminals electrically connected between the respective test signal terminals and the respective signal pins; and first and second EMI filter blocks electrically connected between the first source pin and the first source terminal and between the second source pin and the second source terminal, respectively.

In accordance with the probe card and the IC tester of the present invention, the EMI filter blocks having smaller dimensions can be disposed on the bottom surface of the card plate in the vicinity of the source pins and thus effectively suppress noise entering to the source lines of the IC from the source pins, thereby preventing a penetrating current in the semiconductor circuit and thus melt-down of the probe pins.

Each EMI filter block may include a single EMI filter element or a plurality of EMI filter elements connected in parallel.

The above and other objects, features and advantages of the present invention will be more apparent from the following description, referring to the accompanying drawings.

### BRIEF DESCRIPTION OF THE DRAWINGS

FIG. 1 is a schematic circuit diagram of an IC tester according to a first embodiment of the present invention.

FIG. 2 is a circuit diagram of an EMI filter element in the EMI filter block shown in FIG. 1.

FIG. 3 is a circuit diagram of a modification of the EMI filter element of FIG. 2.

FIG. 4 is a circuit diagram of a probe card in an IC tester according to a second embodiment of the present invention.

### PREFERRED EMBODIMENTS OF THE INVENTION

Now, the present invention is more specifically described with reference to accompanying drawings, wherein similar constituent elements are designated by similar reference numerals.

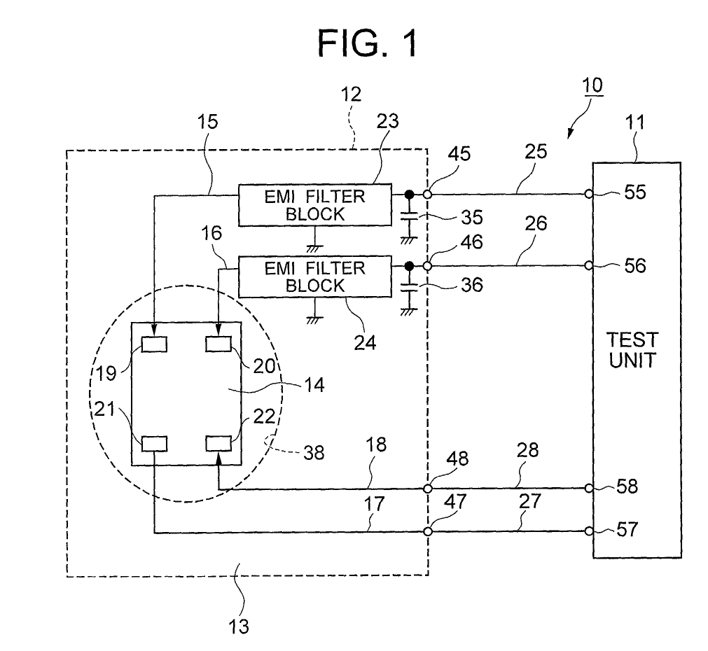

Referring to FIG. 1, an IC tester, generally designated by numeral 10, according to a first embodiment of the present invention includes a test unit 11 and a probe card 12 electrically connected to the test unit 11. The probe card 12 is used for testing an LSI 14 having two different semiconductor circuits including a high-voltage circuit operating on a power source voltage of 80 volts, for example, and a low-voltage circuit operating on a power source voltage of 5 volts, for example, as a logic circuit.

The probe card 12 includes a card plate 13 having a central opening 38 therein, and a plurality of probe pins 15, 16, 17, 18 mounted on the bottom surface of the card plate 13 for allowing slight movements of the probe pins with respect to the card plate 13 in the direction normal to the bottom surface of the card plate 13. The LSI 14 under test mounts thereon a low-voltage source terminal 19 and a high-voltage source terminal 20 as well as a plurality of signal output terminals 21 and a plurality of signal input terminals 22, one of the signal output terminals and one of the signal input terminals being depicted in the figure.

The probe pins include a low-voltage source pin 15 connected to a low-voltage power source supply terminal 55 of the test unit 11 through an electromagnetic interference (EMI) filter block 23, a low-voltage source terminal 45 of the probe card 12 and a low-voltage source line 25, a high-voltage source pin 26 connected to a high-voltage power source supply terminal 56 of the test unit 11 through an EMI filter block 24, a high-voltage source terminal 46 of the probe card 12 and a high-voltage source line 26, a plurality of signal output pins 17 connected to respective signal input terminals 57 of the test unit 11 through respective signal output terminals 47 of the probe card 12 and signal input lines 27, and a plurality of signal input pins 18 connected to the signal output terminals 58 of the test unit 11 through signal input terminals 48 of the probe card 12 and signal output lines 28.

The probe pins 15 to 18 have suitable lengths and are located so that the tips of the probe pins 15 to 18 are in contact with respective electrode pads 19 to 22 when the LSI 14 under test is aligned with the center of the central opening 38 of the card plate 13.

The card plate 13 of the probe card 12 mounts, on the bottom surface thereof, the EMI filter blocks 23 and 24 each including a plurality (n) of EMI filter elements connected in parallel. Each EMI filter element is implemented as a low-pass filter or a surge absorber. Examples of the EMI filter element for use in the present embodiment include an “Emiguard” (trademark) supplied from Murata Mfg. Ltd.

The low-voltage source pin 15 has a base portion connected to one of the terminals of the EMI filter block 23, the other terminal of which is connected to the low-voltage source terminal 45 of the probe card 12. The high-voltage source pin 16 has a base portion connected to one of the terminals of the EMI filter block 24, the other terminal of which is connected to the high-voltage source terminal 46 of the probe card 12. A larger number for n of the parallel EMI filter elements allows the EMI filter block 23 or 24 to have a higher performance for removing noise from the corresponding source voltage.

The other terminal of the EMI filter block 23 or 24 is also connected to one of the terminals of a corresponding bypass capacitor 35 or 36, the other terminal of which is connected to the ground. The bypass capacitor 35 or 36 is a stacked ceramic capacitor mounted on the top surface of the card plate 13.

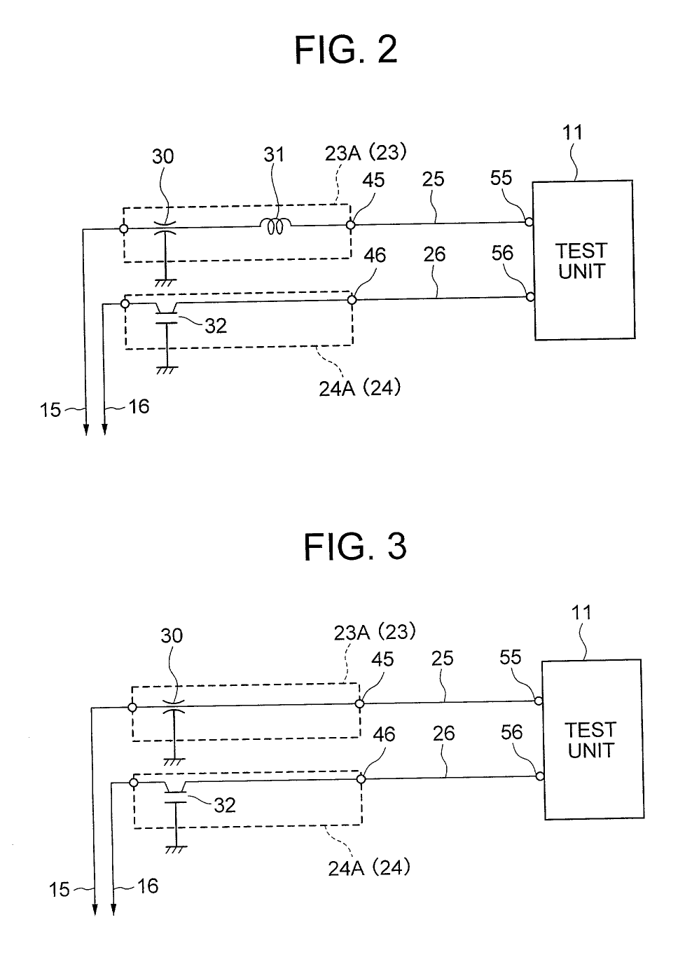

Referring to FIG. 2, each EMI filter element 23A in the low-voltage EMI filter block 23 is implemented by a ferrite bead (or ferrite coil) 31 and a three-terminal capacitor 30 serially and consecutively connected from the low-voltage source terminal 45 to the probe pin 15. Each EMI filter element 24A in the high-voltage EMI filter block 24 is implemented by a three-terminal capacitor 32 having a built-in ferrite bead therein.

Each three-terminal capacitor 30 or 32 has first and second terminals for passing power source current therebetween, and a third terminal capacitively coupled to the first and second terminals and connected to the ground. The three-terminal capacitor 30 or 32 has a capacitive coupling function for increasing the capacitance between the power source line and the ground. The three-terminal capacitor 32 has a higher absorbing function for absorbing a surge voltage such as exceeding the nominal voltage of the high-voltage power source and entering to the high-voltage source line.

The low-voltage three-terminal capacitor 30 has a capacitance of 2000 pF to 2 μF, and the ferrite bead 31 has an electric resistance of 100Ω or more at a frequency of 100 MHz.

Referring to FIG. 3, a modification of the IC tester 10 of the first embodiment includes a low-voltage EMI filter block 23 including a plurality of EMI filter elements 23A each having no ferrite bead, with the other configuration of the IC tester being similar to the first embodiment. The modification has a somewhat limited function for noise reduction, with the other functions being similar to those of the first embodiment.

The probe card 12 of the present embodiment will be discussed hereinbelow, while comparing the same against the conventional probe card, with reference to FIG. 1. The conventional probe card, as described before, has bypass capacitors such as shown in FIG. 1 and formed on the top surface of the card plate 13, without associated EMI filters.

On the other hand, the probe card in the present embodiment has EMI filter blocks for the respective source lines 25 and 26 in association with the bypass capacitors 35 and 46, the EMI filter blocks 23 and 24 effectively removing noise from the source voltages. The low-voltage EMI filter block 23 prevents the malfunction of the low-voltage semiconductor circuit, especially in the power source block thereof to assist the high-voltage semiconductor circuit to be free from the penetrating current. Thus, meltdown of the high-voltage source pin 20 or the signal output probe pins 21 can be suppressed.

The EMI filter block 23 or 24 can be formed with smaller dimensions, as smaller as by about one order, for example, in dimensions compared to the bypass capacitors 35 and 36. Thus, the EMI filter blocks 23 and 24 can be disposed on the bottom surface of the card plate 13 in the close vicinity of the respective source probe pins 15 and 16. This configuration allows an effective removal of noise on the source voltage from the source pin 15 or 16 from which the source voltage enters the power source lines in the IC 14.

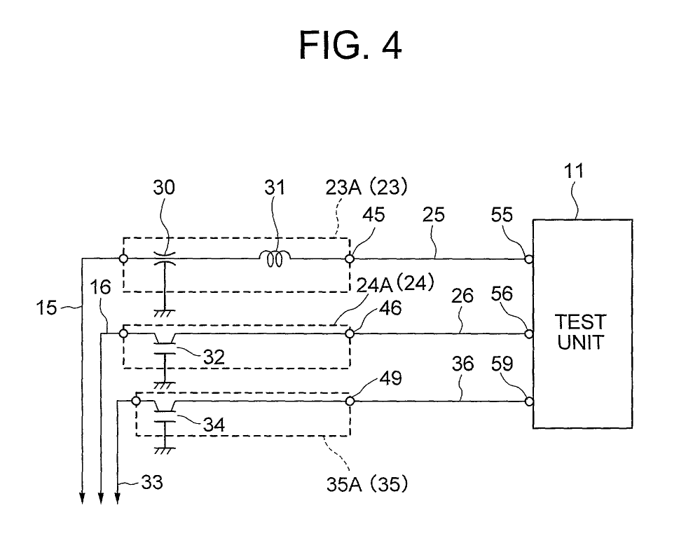

Referring to FIG. 4, a probe card according to a second embodiment of the present invention includes a low-voltage source pin 15, a first high-voltage source pin 16 and a second high-voltage source pin 33. Each source probe pin 15, 16 or 33 is associated with a corresponding EMI filter block 23, 24 or 35. The second high-voltage source has a source voltage higher than the source voltage of the first high-voltage source in this example.

Each EMI filter element 24A or 35A in the high-voltage source EMI filter block 24 or 35 includes a three-terminal capacitor 32 or 34 having therein a built-in ferrite bead, whereas each EMI filter element 23A in the low-voltage source EMI filter block 23 has a ferrite bead 31 and a three-terminal capacitor 30 consecutively connected from the source terminal 45 to the source pin 15.

Since the above embodiments are described only for examples, the present invention is not limited to the above embodiments and various modifications or alterations can be easily made therefrom by those skilled in the art without departing from the scope of the present invention. For example, the present invention can be applied to a probe card having any number of source pins therein.

What is claimed is:

1. A probe card comprising:
a card plate;
a plurality of probe pins mounted on a bottom surface of said card plate and including a first source pin, a second source pin and a plurality of signal pins;
a plurality of probe terminals disposed on said card plate and including a first source terminal electrically connected to said first source pin, a second source terminal connected to said second source pin, and a plurality of signal terminals electrically connected to respective said signal pins; and
first and second EMI filter blocks electrically connected between said first source pin and said first source terminal and between said second source pin and said second source terminal, respectively.

2. The probe card as defined in claim 1, wherein each of said first and second EMI filter blocks includes a plurality of EMI filter elements connected in parallel.

3. The probe card as defined in claim 1, wherein:
said EMI filter element of said first EMI filter block comprises a first three-terminal capacitor and a ferrite bead electrically and consecutively connected from said first source pin to said first source terminal; and
said EMI filter element of said second EMI filter block comprises a second three-terminal capacitor having a built-in ferrite bead.

4. The probe card as defined in claim 1, further comprising a third EMI filter block, wherein said plurality of probe pins further include a third source pin, said plurality of probe terminals further include a third source pin, and said third EMI filter block is electrically connected between said third source pin and said third source terminal.

5. The probe card as defined in claim 1, wherein said first and second EMI filter blocks are mounted on said bottom surface of said card plate.

6. The probe card as defined in claim 1, further comprising first and second bypass capacitors mounted on a top surface of said card plate, said first bypass capacitor being electrically connected between said first source terminal and ground, said second bypass capacitor being electrically connected between said second source terminal and ground.

7. An IC tester comprising a probe card and an associated test unit having a plurality of test terminals including a first power supply terminal, a second power supply terminal and a plurality of test signal terminals, said first power supply terminal supplying a first source voltage which is lower than a second source voltage supplied by said second power supply terminal, said probe card including:
a card plate;
a plurality of probe pins electrically connected to respective said test terminals and mounted on a bottom surface of said card plate and including a first source pin, a second source pin and a plurality of signal pins;
a plurality of probe terminals disposed on said card plate and including a first source terminal electrically connected between said first power supply terminal and said first source pin, a second source terminal electrically connected between said second supply terminal and said second source pin, and a plurality of probe signal terminals electrically connected between respective said test signal terminals and respective said signal pins; and
first and second EMI filter blocks electrically connected between said first source pin and said first source terminal and between said second source pin and said second source terminal, respectively.

8. The IC tester as defined in claim 7, wherein each of said first and second EMI filter blocks includes a plurality of EMI filter elements connected in parallel.

9. The IC tester as defined in claim 7, wherein:
said EMI filter element of said first EMI filter block comprises a first three-terminal capacitor and a ferrite bead consecutively connected from said first source pin to said first source terminal; and
said EMI filter element of said second EMI filter block comprises a second three-terminal capacitor having a built-in ferrite bead.

10. The IC tester as defined in claim 7, wherein said probe card further includes a third EMI filter block, said plurality of probe pins further include a third source pin, said plurality of probe terminals further include a third source pin, and said third EMI filter block is electrically connected between said third source pin and said third source terminal.

11. The IC tester as defined in claim 7, wherein said first and second EMI filter blocks are mounted on said bottom surface of said card plate.

12. The IC tester as defined in claim 7, wherein said probe card further includes first and second bypass capacitors mounted on a top surface of said card plate, said first bypass capacitor being electrically connected between said first source terminal and ground, said second bypass capacitor being electrically connected between said second source terminal and ground.
